(19) United States
(12) Patent Application Publication
(10) Pub. No.: US 2022/0352420 A1
(43) Pub. Date: Nov. 3, 2022

(54) DISPLAY DEVICE

(71) Applicant: Samsung Display Co., LTD., Yongin-si (KR)

(72) Inventors: Sung Kook PARK, Yongin-si (KR); Min Woo KIM, Yongin-si (KR); Ja Eun LEE, Yongin-si (KR); Jin Woo CHOI, Yongin-si (KR)

(73) Assignee: Samsung Display Co., LTD., Yongin-si (KR)

(21) Appl. No.: 17/561,056

(22) Filed: Dec. 23, 2021

(30) Foreign Application Priority Data
Apr. 30, 2021 (KR) 10-2021-0056892

(51) Int. Cl. H01L 33/38; H01L 27/15; H01L 33/62; H01L 33/50

(52) U.S. Cl. CPC H01L 33/382; H01L 27/156; H01L 33/62; H01L 33/505

(57) ABSTRACT

A display device may include light emitting elements, a first electrode and a second electrode electrically connected to each of the light emitting elements, a pixel circuit electrically connected to at least one of the light emitting elements. The pixel circuit may be disposed in each of a plurality of pixel circuit areas that are disposed in a matrix form defined by a first direction and a second direction intersecting the first direction, a first contact portion and a second contact portion may be disposed in each of the plurality of pixel circuit areas, wherein the first contact portion electrically connects the pixel circuit and the first electrode, and the second contact portion electrically connects a common power line and the second electrode, and in a plan view, the first contact portion and the second contact portion may be alternately disposed along the first direction.

### CROSS-REFERENCE TO RELATED APPLICATION(S)

This application claims priority to and benefits of Korean Patent Application No. 10-2021-0056892 under 35 U.S.C. § 119, filed on Apr. 30, 2021 in the Korean Intellectual Property Office, the entire contents of which are herein incorporated by reference.

### BACKGROUND

### 1. Technical Field

The disclosure relates to a display device.

### 2. Description of the Related Art

In recent years, as interest in information display is increasing, research and development for a display device is continuously being conducted.

### SUMMARY

An aspect of the disclosure is to provide a display device in which resolution is improved and a movement path of an electrical signal for a pixel is efficiently defined.

Aspects of the disclosure are not limited to the above, and other technical aspects which are not described will be clearly understood by those skilled in the art from the following description.

According to an embodiment of the disclosure, a display device may include light emitting elements disposed on a substrate, a first electrode and a second electrode that are disposed on the substrate and electrically connected to each of the light emitting elements, a pixel circuit electrically connected to at least one of the light emitting elements. The pixel circuit may be disposed in each of a plurality of pixel circuit areas that are disposed in a matrix form defined by a first direction and a second direction intersecting the first direction, a first contact portion and a second contact portion may be disposed in each of the plurality of pixel circuit areas, wherein the first contact portion electrically connects the pixel circuit and the first electrode, and the second contact portion electrically connects a common power line and the second electrode, the first contact portion and the second contact portion may be alternately disposed along the first direction in a plan view.

According to an embodiment, the display device may further include a first sub pixel area from which light of a first color may be emitted, a second sub pixel area from which light of a second color may be emitted, and a third sub pixel area from which light of a third color may be emitted, wherein the light emitting elements may include a first light emitting element overlapping the first sub pixel area, a second light emitting element overlapping the second sub pixel area, and a third light emitting element overlapping the third sub pixel area.

According to an embodiment, the pixel circuit may include a transistor and a storage capacitor, the pixel circuit may be electrically connected to any one of first signal lines extending in the first direction, and the pixel circuit may be electrically connected to any one of second signal lines extending in the second direction, and each of the plurality of pixel circuit areas may be disposed in an overlap area between an first area and a second area, wherein the first area may be between the first signal lines adjacent in the second direction, and the second area may be between the second signal lines adjacent in the first direction.

According to an embodiment, the plurality of pixel circuit areas may include a first pixel circuit area in which a first pixel circuit electrically connected to the first light emitting element may be disposed, a second pixel circuit area in which a second pixel circuit electrically connected to the second light emitting element may be disposed, and a third pixel circuit area in which a third pixel circuit electrically connected to the third light emitting element may be disposed.

According to an embodiment, the display device may further include a color conversion portion defining the first sub pixel area, the second sub pixel area, and the third sub pixel area, wherein the color conversion portion may include a first wavelength conversion pattern overlapping the first sub pixel area, a second wavelength conversion pattern overlapping the second sub pixel area, and a light transmission pattern overlapping the third sub pixel area, and the first light emitting element, the second light emitting element, and the third light emitting element may emit light of the third color.

According to an embodiment, the first contact portion may be disposed in one of the plurality of pixel circuit areas and the second contact portion may be disposed in another of the plurality of pixel circuit areas, another second contact portion may be disposed in the one of the plurality of pixel circuit areas and another first contact portion may be disposed in the another of the plurality of pixel circuit areas, and the one of the plurality of pixel circuit areas and the another of the plurality of pixel circuit areas may be adjacent to each other in the first direction.

According to an embodiment, the first sub pixel area, the second sub pixel area, and the third sub pixel area may have a first shape, and each of the plurality of pixel circuit areas may have a second shape different from the first shape.

According to an embodiment, the first shape may be a rhombus shape, and the second shape may be a rectangular shape.

According to an embodiment, each of the plurality of pixel circuit areas may overlap at least a portion of each of the first sub pixel area, the second sub pixel area, and the third sub pixel area in a plan view.

According to an embodiment, the first pixel circuit area and the first sub pixel area may partially overlap each other in a plan view, the second pixel circuit area and the second sub pixel area may partially overlap each other in a plan view, and the third pixel circuit area and the third sub pixel area may partially overlap each other in a plan view.

According to an embodiment, the first contact portion and the second contact portion may be disposed in each of the plurality of pixel circuit areas.

According to an embodiment, the first contact portion may include a (1-1)-th contact portion disposed adjacent to a first side of a first circuit area, which may be one of the plurality of pixel circuit areas, and a (1-2)-th contact portion disposed adjacent to a second side of a second circuit area which may be another of the plurality of pixel circuit areas, and the second side may be another side of the first side in the second direction.

According to an embodiment, the second contact portion may include a (2-1)-th contact portion disposed adjacent to the first side in the second circuit area, and a (2-2)-th contact portion disposed adjacent to the second side in the first circuit area.

According to an embodiment, the first contact portion may overlap at least one of the light emitting elements in a plan view.

According to an embodiment, the common power line may provide a cathode signal to the light emitting elements.

According to an embodiment, the display device may further include a partition wall structure disposed between areas adjacent to each other among the first sub pixel area, the second sub pixel area, and the third sub pixel area, in a plan view, and the light emitting elements may be electrically connected to the common power line through the second electrode, the partition wall structure, and the second contact portion.

According to an embodiment, the first contact portion and the second contact portion may be alternately disposed along the second direction, in a plan view.

According to an embodiment, the display device may further include a display area, a non-display area surrounding at least a portion of the display area, a cover layer disposed in the non-display area adjacent to a boundary area between the display area and the non-display area, and a sub pixel area overlapping at least a portion of the light emitting elements, and at least a portion of the sub pixel area may overlap the cover layer in a plan view.

According to an embodiment, the cover layer may define the boundary area between the display area and the non-display area.

According to another embodiment of the disclosure, a display device may include light emitting elements disposed on a substrate and including a first light emitting element disposed in a first sub pixel area, and a second light emitting element disposed in a second sub pixel area that is adjacent to the first sub pixel area, a first electrode and a second electrode that are disposed on the substrate and electrically connected to each of the light emitting elements, a pixel circuit electrically connected to at least a portion of the light emitting elements, and a partition wall structure disposed between the first sub pixel area and the second sub pixel area. The pixel circuit and the first electrode may be electrically connected through a first contact portion, a common power line and the second electrode may be electrically connected through a second contact portion, the pixel circuit may be disposed in each of a plurality of pixel circuit areas that are disposed in a matrix form defined by a row direction and a column direction, a shape of each of the first sub pixel area and the second sub pixel area and a shape of the pixel circuit area may be different from each other, and the common power line may be electrically connected to the first light emitting element and the second light emitting element through the second contact portion and the partition wall structure.

A solution of the disclosure is not limited to the above-described solutions, and solutions which are not described will be clearly understood by those skilled in the art from the specification and the accompanying drawings.

According to an embodiment of the disclosure, a display device in which resolution may be improved and a movement path of an electrical signal for a pixel may be efficiently defined is provided.

An effect of the disclosure is not limited to the above, and effects which are not described will be clearly understood by those skilled in the art from the specification and the accompanying drawings.

### BRIEF DESCRIPTION OF THE DRAWINGS

The above and other features of the disclosure will become more apparent by describing in further detail embodiments thereof with reference to the accompanying drawings, in which:

FIG. 1 is a perspective view schematically illustrating a display device according to an embodiment;

FIG. 2 is a plan view schematically illustrating a display device according to an embodiment;

FIG. 3 is a diagram schematically illustrating a pixel circuit included in a pixel according to an embodiment;

FIG. 4 is an enlarged schematic view of EA1 of FIG. 2;

FIG. 5 is a plan view schematically illustrating a pixel according to an embodiment;

FIG. 6 is a schematic cross-sectional view taken along I˜I′ of FIG. 5;

FIG. 7 is a schematic cross-sectional view taken along II˜II′ of FIG. 5;

FIG. 8 is a schematic cross-sectional view taken along II˜II′ of FIG. 5, and is a view in which some modified embodiments are reflected;

FIG. 9 is a plan view schematically illustrating a pixel according to another embodiment;

FIG. 10 is an enlarged schematic view of EA2 of FIG. 2;

FIG. 11 is a cross-sectional schematic view taken along of FIG. 10; and

FIGS. 12 to 15 are diagrams schematically illustrating an example to which a display device according to an embodiment may be applied.

### DETAILED DESCRIPTION OF THE EMBODIMENTS

Since the embodiments described in the specification are for clearly describing the spirit of the disclosure to those skilled in the art to which the disclosure pertains, the disclosure is not limited by the embodiments described in the specification. The scope of the disclosure should be interpreted as including modifications or variations that do not depart from the spirit of the disclosure.

As used herein, the singular forms, “a,” “an,” and “the” are intended to include the plural forms as well (and vice versa), unless the context clearly indicates otherwise.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The drawings attached to the specification are intended to easily describe the disclosure. Since the shape shown in the drawings may be exaggerated and displayed as necessary to help understanding of the disclosure, the disclosure is not limited by the drawings.

In the specification, when it is determined that detailed description of a known configuration or function related to the disclosure may obscure the subject matter of the disclosure, detailed description thereof may be omitted.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

It will be understood that the terms “connected to” or “coupled to” may include a physical or electrical connection or coupling.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

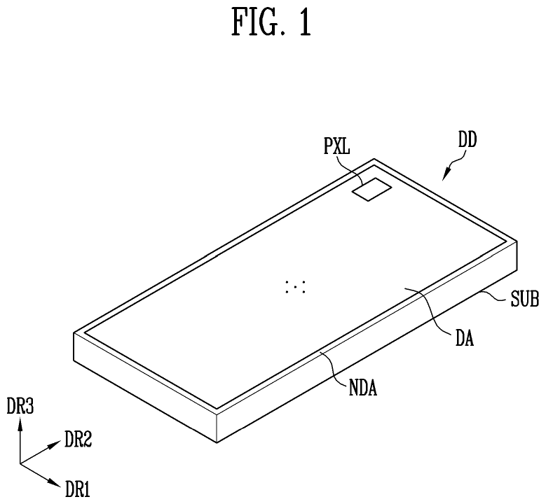

The disclosure relates to a display device. Hereinafter, a display device according to an embodiment is described with reference to FIGS. 1 to 15.

FIG. 1 is a perspective view schematically illustrating a display device according to an embodiment.

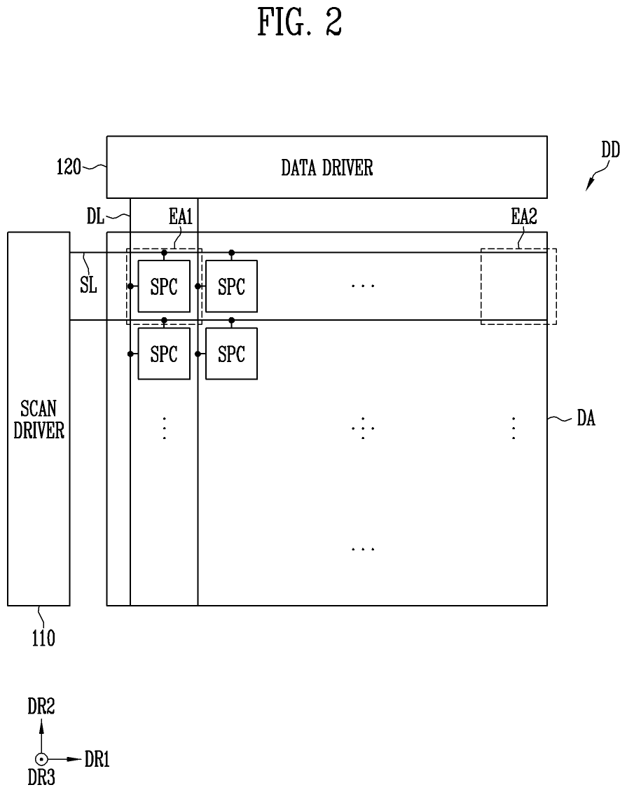

FIG. 2 is a plan view schematically illustrating a display device according to an embodiment.

The display device DD according to an embodiment may be configured to emit light.

Referring to FIGS. 1 and 2, the display device DD may include a substrate SUB, a pixel PXL, a scan driver 110, and a data driver 120. According to an embodiment, the display device DD may further include lines and pads.

The substrate SUB may configure a base member of the display device DD. The substrate SUB may be a rigid or flexible substrate or film, but is not limited to a specific example.

The display device DD may include a display area DA and a non-display area NDA. The non-display area NDA may mean an area other than the display area DA. The non-display area NDA may surround at least a portion of the display area DA.

According to an embodiment, the display area DA may mean an area where a pixel PXL may be disposed and thus light may be emitted. The non-display area NDA may mean an area other than the display area DA. According to an example, the scan driver 110, the data driver 120, the lines, and the pads may be disposed in the non-display area NDA.

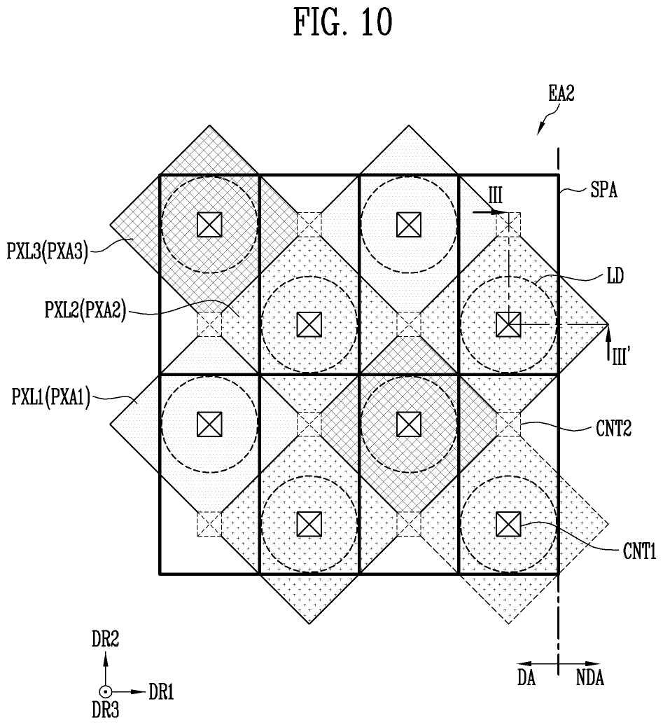

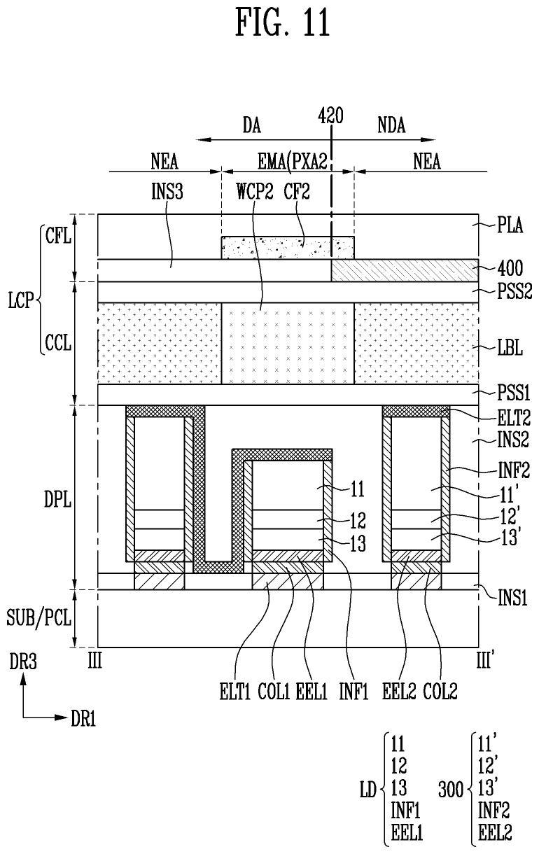

According to an embodiment, a boundary line (refer to ‘420’ of FIG. 11) between the display area DA and the non-display area NDA may be defined by a cover layer (refer to ‘400’ of FIG. 11). Details in this regard are described later with reference to FIGS. 10 and 11.

The pixel PXL may be disposed on the substrate SUB. According to an example, the pixels PXL may be arranged according to a stripe, a PENTILE™ arrangement structure, or the like, but are not limited to a specific example.

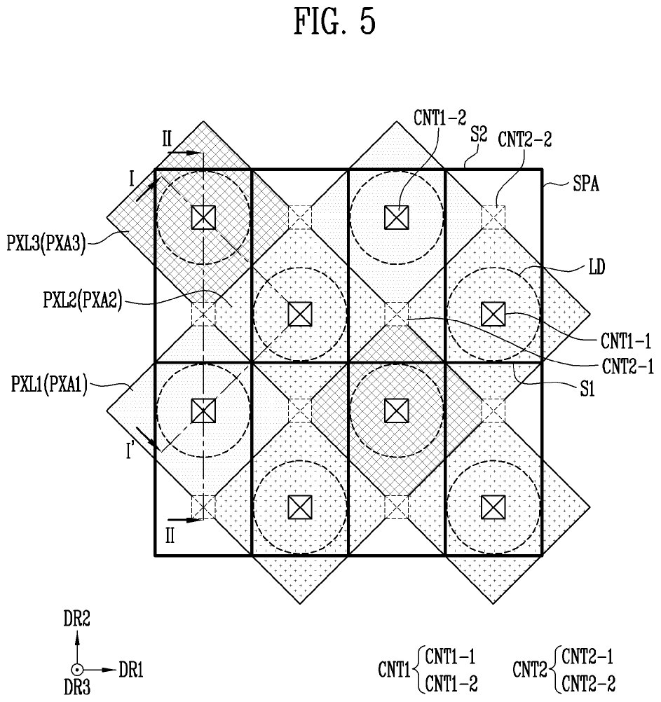

The pixel PXL may include a first sub pixel (refer to ‘PXL1’ of FIG. 5), a second sub pixel (refer to ‘PXL2’ of FIG. 5), and a third sub pixel (refer to ‘PXL3’ of FIG. 5).

According to an embodiment, at least one of the first to third sub pixels PXL1, PXL2, and PXL3 disposed to be adjacent to each other may configure one pixel unit capable of emitting light of various colors. For example, each of the first to third sub pixels PXL1, PXL2, and PXL3 may be a sub pixel that emits light of a predetermined color.

For example, the first sub pixel PXL1 may be a red pixel emitting red light, the second sub pixel PXL2 may be a green pixel emitting green light, and the third sub pixel PXL3 may be a blue pixel emitting blue light. However, the color, type, number, and/or the like of pixels PXL configuring each pixel unit are/is not limited to a specific example.

The pixel PXL may be electrically connected to the scan driver 110 through a scan line SL, and may be electrically connected to the data driver 120 through a data line DL.

The scan driver 110 may be disposed on one side of the display area DA. The scan driver 110 may supply a scan signal to the pixel PXL through the scan line SL.

The data driver 120 may be disposed on one side of the display area DA. The data driver 120 may supply a data signal to the pixel PXL through the data line DL.

According to an embodiment, the pixel PXL may emit light based on an electrical signal provided through the scan driver 110 and the data driver 120.

The scan line SL may be connected to a pixel circuit SPC. According to an example, the scan line SL may extend in a first direction DR1.

The data line DL may be connected to the pixel circuit SPC. According to an example, the data line DL may extend in a second direction DR2 intersecting (or non-parallel) with the first direction DR1.

According to an example, the scan line SL may be referred to as a first signal line, and the data line DL may be referred to as a second signal line.

However, the disclosure is not limited to the above-described example. According to an embodiment, the scan line SL may extend in the second direction DR2, and the data line DL may extend in the first direction DR1.

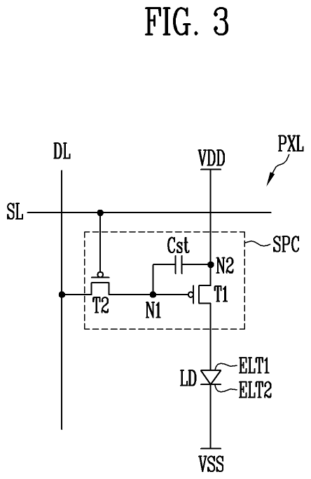

The pixel circuit SPC may be electrically connected to a light emitting element (refer to “LD” of FIG. 3) included in at least one of the first to third sub pixels PXL1, PXL2, and PXL3. The pixel circuit SPC may be configured to drive at least one of the first to third sub pixels PXL1, PXL2, and PXL3.

According to an embodiment, the pixel circuit SPC may be collectively referred to as a single circuit provided to configure the pixel PXL.

According to an embodiment, pixel circuits SPC may be provided and may be arranged in a matrix form defined by a circuit row direction and a circuit column direction. For example, one pixel circuit SPC may be disposed in an i-th circuit row and a j-th circuit column.

According to an embodiment, the pixel circuit SPC (for example, a first pixel circuit) corresponding to the first sub pixel PXL1 may be electrically connected to the light emitting element LD (for example, a first light emitting element) disposed in a first sub pixel area PXA1. The pixel circuit SPC (for example, a second pixel circuit) corresponding to the second sub pixel PXL2 may be electrically connected to the light emitting element LD (for example, a second light emitting element) disposed in a second sub pixel area PXA2. The pixel circuit SPC (for example, a third pixel circuit) corresponding to the third sub pixel PXL3 may be electrically connected to the light emitting element LD (for example, a third light emitting element) disposed in a third sub pixel area PXA3.

According to an embodiment, the pixel circuits SPC may be respectively disposed in an individually defined pixel circuit area SPA. The pixel circuit SPC may be disposed in each of multiple pixel circuit areas (refer to “SPA” of FIG. 5) arranged in a matrix form defined by the row direction according to the first direction DR1 and the column direction according to the second direction DR2 intersecting (or non-parallel) with the first direction DR1.

For example, the pixel circuit SPC (for example, the first pixel circuit) configured to drive the first sub pixel PXL1 may be disposed in the corresponding pixel circuit area SPA (for example, a first pixel circuit area).

The pixel circuit SPC (for example, the second pixel circuit) configured to drive the second sub pixel PXL2 may be disposed in the corresponding pixel circuit area SPA (for example, a second pixel circuit area).

The pixel circuit SPC (for example, the third pixel circuit) configured to drive the third sub pixel PXL3 may be disposed in the corresponding pixel circuit area SPA (for example, a third pixel circuit area).

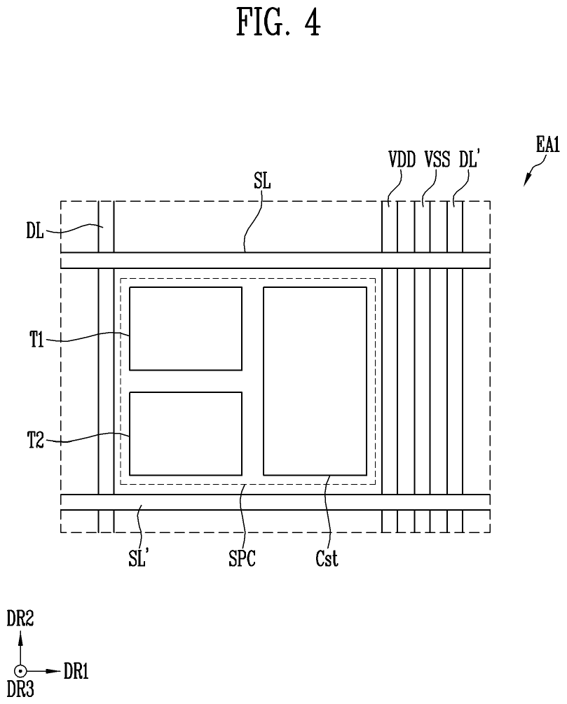

Hereinafter, the pixel circuit SPC according to an embodiment is more specifically described with reference to FIGS. 3 and 4.

FIG. 3 is a diagram schematically illustrating a pixel circuit included in a pixel according to an embodiment.

FIG. 4 is an enlarged schematic view of EA1 of FIG. 2. FIGS. 3 and 4 schematically illustrate configurations related to a single pixel circuit SPC.

The pixel circuit SPC shown in FIG. 3 may be a pixel circuit of any one of the first to third sub pixels PXL1, PXL2, and PXL3. FIG. 3 shows an electrical connection relationship between components included in the pixel PXL that may be applied to an active display device. However, types of the components included in the pixel PXL to which an embodiment of the disclosure may be applied are not limited thereto.

Referring to FIG. 3, the pixel PXL may include the light emitting element LD that may emit light of a luminance corresponding to the data signal, and the pixel circuit SPC.

According to an embodiment, the light emitting element LD may be connected between a first power line VDD and a second power line VSS. An end portion (for example, a P-type semiconductor) of the light emitting element LD may be connected to the first power line VDD via the pixel circuit SPC and a first electrode ELT1, and another end portion (for example, an N-type semiconductor) of the light emitting element LD may be connected to the second power line VSS via a second electrode ELT2.

According to an embodiment, the light emitting elements LD may be connected to each other through various connection structures between the first power line VDD and the second power line VSS. For example, the light emitting elements LD may be connected to each other only in parallel or may be connected to each other only in series. In other embodiments, the light emitting elements LD may be connected in a series/parallel mixed structure.

According to an embodiment, the first power line VDD and the second power line VSS may have different potentials so that the light emitting elements LD may emit light.

The first power line VDD and the second power line VSS may have a potential difference of a level at which light may be emitted during an emission period of the pixel PXL. For example, the first power line VDD may be set to a potential higher than that of the second power line VSS.

According to an embodiment, the pixel circuit SPC may connect between the first power line VDD and the light emitting element LD. The pixel circuit SPC may include transistors and a storage capacitor Cst. For example, the pixel circuit SPC may include a first transistor T1, a second transistor T2, and the storage capacitor Cst.

According to an embodiment, an electrode of the first transistor T1 may be connected to the first power line VDD, and another electrode may be connected to one electrode (for example, an anode electrode) of the light emitting element LD. A gate electrode of the first transistor T1 may be connected to a first node N1. The first transistor T1 may control a current flowing through the light emitting element LD in response to a voltage applied through the first node N1.

According to an embodiment, an electrode of the second transistor T2 may be connected to the data line DL, and another electrode may be connected to the first node N1. A gate electrode of the second transistor T2 may be connected to the scan line SL. In case that the scan signal is supplied from the scan line SL, the second transistor T2 may be turned on, and at this time, the second transistor T2 may transmit the data signal provided from the data line DL to the first node N1.

The storage capacitor Cst may be connected between the first node N1 (or the gate electrode of the first transistor T1) and a second node N2 (or an electrode of the first transistor T1). The storage capacitor Cst may store information on a difference between a voltage of the first node N1 and a voltage of the second node N2.

A structure of the pixel circuit SPC is not limited to the structure shown in FIG. 3, and various types of structures may be implemented. For example, according to an embodiment, the pixel circuit SPC may further include a third transistor for calculating a mobility of the first transistor T1 and a change amount of a threshold voltage.

Referring to FIG. 4, individual configurations of the pixel circuit SPC are briefly shown.

Referring to FIG. 4, the pixel circuit SPC may be disposed adjacent to the scan line SL and the data line DL.

The pixel circuit SPC may be electrically connected to any one of the scan lines SL and may be electrically connected to any one of the data lines DL.

According to an embodiment, the scan line SL and the data line DL intersecting each other may define the pixel circuit area SPA, which may be an area in which the pixel circuit SPC may be disposed. An area where an area between the scan lines SL adjacent to each other in the second direction DR2 and an area between the data lines DL adjacent to each other in the first direction DR1 overlap may be defined as a pixel circuit area SPA. For example, the pixel circuit SPC may be disposed in an area overlapping an area between an i-th scan line SL and an (i+1)-th scan line SL and an area between a j-th data line DL and a (j+1)-th data line DL.

For example, a first area between the data line DL and an adjacent data line DL′ adjacent to the data line DL in the first direction DR1 may be defined, and a second area between the scan line SL and an adjacent scan line SL′ adjacent to the scan line SL in the second direction DR2 may be defined. At this time, the pixel circuit SPC may be disposed in an overlapping area between the first area and the second area.

According to an embodiment, the pixel circuit area SPA may be determined by a direction in which the data line DL and the scan line SL extend. For example, the area in which the pixel circuit SPC may be disposed may be determined by a direction in which the data line DL may be extended and spaced apart from the adjacent data line DL and a direction in which the scan line SL may be extended and spaced apart from the adjacent scan line SL. Accordingly, the pixel circuit area SPA may be a generally rectangular area, but is not limited thereto. Hereinafter, for convenience of description, an embodiment in which the pixel circuit area SPA may be a rectangle is described.

Hereinafter, a structure of the pixel PXL according to an embodiment is described in more detail with reference to FIGS. 5 to 11.

FIGS. 5 to 8 are diagrams illustrating the pixel PXL included in the display device DD according to an embodiment. FIGS. 10 and 11 are diagrams illustrating an area between the display area DA and the non-display area NDA.

First, the display device DD according to an embodiment is described with reference to FIGS. 5 to 8.

FIG. 5 is a plan view schematically illustrating a pixel according to an embodiment.

In FIG. 5, the display device DD according to an embodiment is shown based on a positional relationship between the pixel circuit SPC and the first to third sub pixel areas PXA1, PXA2, and PXA3 respectively defining the first to third sub pixels PXL1, PXL2, and PXL3. In FIG. 5, the pixel circuit area SPA in which the pixel circuit SPC may be disposed is specified by a thick line.

In FIG. 5, the light emitting element LD is shown by a dotted circular line. For example, in FIG. 5, a cylindrical light emitting element LD, in which a circular bottom surface may be observed in a plan view, is shown. However, the disclosure is not limited thereto, and the light emitting element LD may have another shape according to an embodiment. For example, in case that the light emitting element LD has a rectangular parallelepiped shape, in a plan view, a quadrangle shape may be observed.

At least some of the pixel circuit areas SPA may be sequentially arranged in the first direction DR1. At least some of the pixel circuit areas SPA may be sequentially arranged in the second direction DR2.

At least some of the first to third sub pixel areas PXA1, PXA2, and PXA3 may be sequentially arranged in the first direction DR1. At least some of the first to third sub pixel areas PXA1, PXA2, and PXA3 may be sequentially arranged in the second direction DR2. For example, referring to FIG. 5, the first sub pixel area PXA1 and the third sub pixel area PXA3 may be arranged in a first column, and the first sub pixel area PXA1 and the third sub pixel area PXA3 may be arranged in a first row of FIG. 5.

Here, the first sub pixel area PXA1 may be a position where the first sub pixel PXL1 may be defined, and may mean an area in which light of a first color may be emitted. The second sub pixel area PXA2 may be a position where the second sub pixel PXL2 may be defined, and may mean an area in which light of a second color may be emitted. The third sub pixel area PXA3 may be a position where the third sub pixel PXL3 may be defined, and may mean an area in which light of a third color may be emitted.

According to an embodiment, the light emitting elements LD disposed in the first to third sub pixel areas PXA1, PXA2, and PXA3 may be electrically connected to the pixel circuit SPC.

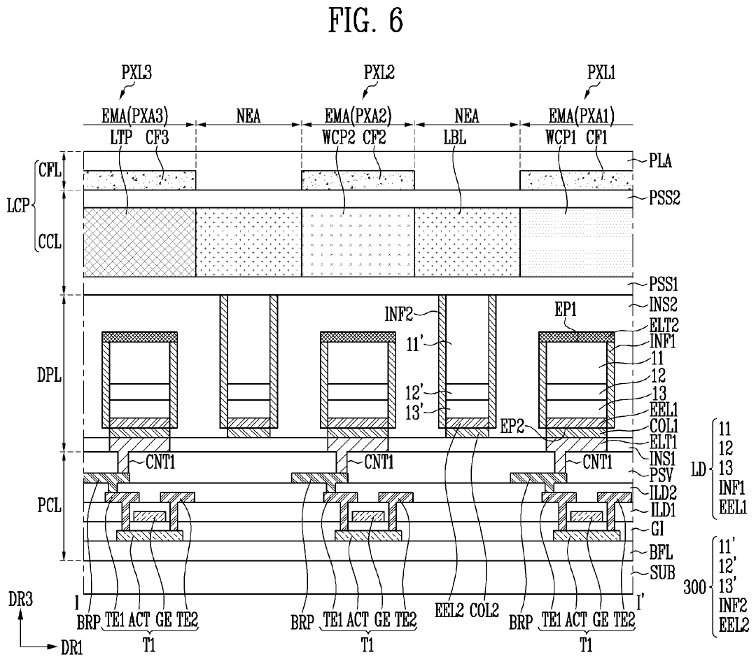

For example, the light emitting elements LD may be electrically connected to the pixel circuit SPC through a first contact portion CNT1 and the first electrode (refer to ‘ELT1’ of FIG. 6), and may receive an anode signal through the first contact portion CNT1.

According to an embodiment, the light emitting elements LD disposed in the first to third sub pixel areas PXA1, PXA2, and PXA3 may be electrically connected to the second electrode ELT2.

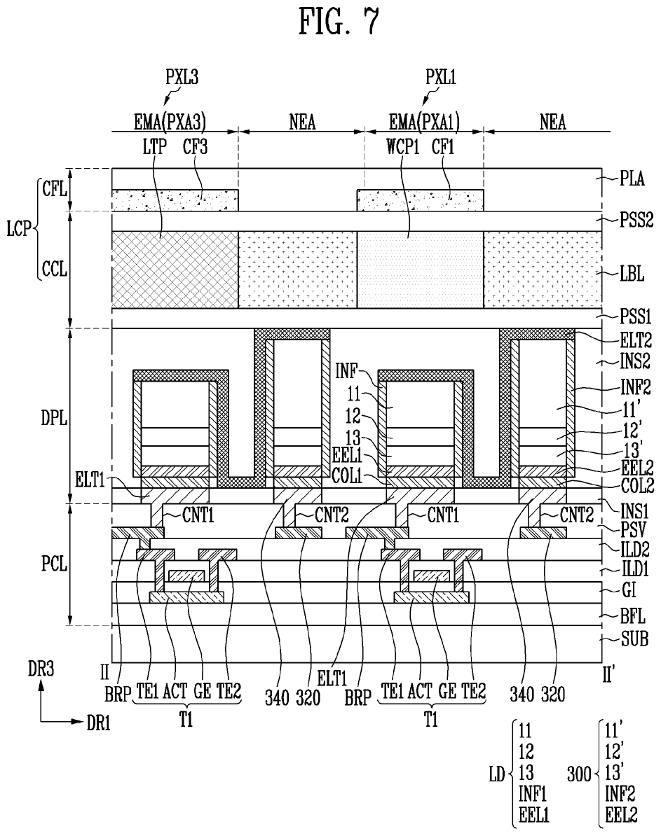

For example, the light emitting elements LD may be electrically connected to the second power line VSS through a second contact portion CNT2, the second electrode ELT2, and a common power line (refer to ‘320’ of FIG. 7). For example, the light emitting elements LD may receive a cathode signal through the second contact portion CNT2.

At least one first contact portion CNT1 may be disposed in the pixel circuit area SPA. According to an embodiment, the first contact portion CNT1 may overlap the light emitting element LD in a plan view. For example, the first electrode ELT1, the first contact portion CNT1, and the light emitting element LD may overlap each other in a plan view.

According to an embodiment, the first contact portion CNT1 may be disposed in each of the first to third sub pixel areas PXA1, PXA2, and PXA3. According to an example, the light emitting element LD disposed in the first to third sub pixel areas PXA1, PXA2, and PXA3 may be electrically connected to the pixel circuit SPC through the first contact portion CNT1. Accordingly, the light emitting element LD defined in any one of the first to third sub pixels PXL1, PXL2, and PXL3 may receive the anode signal provided from the pixel circuit SPC.

In the drawing, only one light emitting element LD may be disposed in each of the first to third sub pixels PXL1, PXL2, and PXL3, but the disclosure is not limited thereto. For example, multiple light emitting elements LD may be disposed in each of the first to third sub pixels PXL1, PXL2, and PXL3.

According to an embodiment, each of the first contact portion CNT1 and the second contact portion CNT2 may be disposed in the individual pixel circuit area SPA.

According to an embodiment, the first contact portion CNT1 may be disposed adjacent to a side and the second contact portion CNT2 may be disposed adjacent to another side in the pixel circuit area SPA.

According to an embodiment, the first contact portion CNT1 may include a (1-1)-th contact portion CNT1-1 and a (1-2)-th contact portion CNT1-2. For example, the (1-1)-th contact portion CNT1-1 may be disposed adjacent to a first side S1 of the corresponding pixel circuit area SPA, and the (1-2)-th contact portion CNT1-2 may be disposed adjacent to a second side S2 of the corresponding pixel circuit area SPA. The second side S2 may mean another side of the first side Si based on the second direction DR2.

At least one second contact portion CNT2 may be disposed in the pixel circuit area SPA. According to an example, the second contact portion CNT2 may not overlap the light emitting element LD in a plan view.

According to an embodiment, the second contact portion CNT2 may be disposed in each of the first to third sub pixel areas PXA1, PXA2, and PXA3. According to an example, the light emitting element LD disposed in the first to third sub pixel areas PXA1, PXA2, and PXA3 may be electrically connected to the second electrode ELT2. At this time, the second electrode ELT2 may be electrically connected to the common power line 320 through the second contact portion CNT2. Accordingly, the light emitting element LD defined in any one of the first to third sub pixels PXL1, PXL2, and PXL3 may receive the cathode signal provided from the common power line 320.

According to an embodiment, at least a portion of the second contact portion CNT2 may be disposed adjacent to a side of the pixel circuit area SPA, and another at least portion of the second contact portion CNT2 may be disposed adjacent to another side of the pixel circuit area SPA.

According to an embodiment, the second contact portion CNT2 may include a (2-1)-th contact portion CNT2-1 and a (2-2)-th contact portion CNT2-2. For example, the (2-1)-th contact portion CNT2-1 may be disposed adjacent to the first side S1 of the corresponding pixel circuit area SPA, and the (2-2)-th contact portion CNT2-2 may be disposed adjacent to the second side S2 of the corresponding pixel circuit area SPA.

Accordingly, the (1-1)-th contact portion CNT1-1 may be disposed on the first side Si of any one (for example, the first circuit area) of the pixel circuit areas SPA, and the (2-2)-th contact portion CNT2-2 may be disposed on the second side S2.

The (2-1)-th contact portion CNT2-1 may be disposed on the first side S1 of another one (for example, the second circuit area) of the pixel circuit areas SPA, and the (1-2)-th contact portion CNT1-2 may be disposed on the second side S2.

According to an embodiment, in a plan view, the first contact portions CNT1 and the second contact portions CNT2 may be alternately disposed along the first direction DR1. Each of the (1-1)-th contact portion CNT1-1 and the (2-1)-th contact portion CNT2-1 may be disposed adjacent to one side of the pixel circuit area SPA, and may be alternately arranged along the first direction DR1. The (1-2)-th contact portion CNT1-2 and the (2-2)-th contact portion CNT2-2 may be disposed adjacent to another side of the pixel circuit area SPA, and may be alternately arranged along the first direction DR1.

For example, referring to FIG. 5, the first contact portion CNT1 disposed in any one of the pixel circuit areas SPA may be alternately arranged along the first direction DR1 with the second contact portion CNT2 disposed in the pixel circuit area SPA adjacent in the first direction DR1. The second contact portion CNT2 disposed in any one of the pixel circuit areas SPA may be alternately disposed along the first direction DR1 with the first contact portion CNT1 disposed in the pixel circuit area SPA adjacent in the first direction DR1.

According to an embodiment, in a plan view, the first contact portion CNT1 and the second contact portion CNT2 may be alternately disposed along the second direction DR2. For example, the (1-2)-th contact portion CNT1-2 and the (2-1)-th contact portion CNT2-1 may be alternately arranged along the second direction DR2. The (2-2)-th contact portion CNT2-2 and the (1-1)-th contact portion CNT1-1 may be alternately arranged along the second direction DR2.

A connection structure between the first contact portion CNT1 and the second contact portion CNT2 is not limited to the above-described embodiment. According to an embodiment, at least some of the first contact portions CNT1 may be adjacent to each other in the first direction DR1, and at least some of the second contact portions CNT2 may be adjacent to each other in the first direction DR1.

According to an embodiment, a side of the pixel circuit area SPA may intersect (or non-parallel) with a side of each of the first to third sub pixel areas PXA1, PXA2, and PXA3.

The pixel circuit area SPA and each of the first to third sub pixel areas PXA1, PXA2, and PXA3 may have different shapes.

For example, each of the first to third sub pixel areas PXA1, PXA2, and PXA3 may have a rhombus shape (for example, referred to as a first shape), and the pixel circuit area SPA may have an overall rectangular shape (for example, referred to as a second shape). According to an embodiment, each of the first to third sub pixel areas PXA1, PXA2, and PXA3 may have a quadrangle shape. However, the disclosure is not limited thereto, and the pixel circuit area SPA and the first to third sub pixel areas PXA1, PXA2, and PXA3 respectively having various shapes may be provided according to an embodiment.

According to an embodiment, each of the first to third sub pixel areas PXA1, PXA2, and PXA3 may overlap multiple of pixel circuit areas SPA in a plan view.

For example, any one of the second sub pixel areas PXA2 shown in FIG. 5 may overlap adjacently disposed four pixel circuit areas SPA, in a plan view.

According to an embodiment, the single pixel circuit area SPA may overlap the adjacently disposed first to third sub pixel areas PXA1, PXA2, and PXA3. One pixel circuit area SPA may overlap adjacently disposed two second sub pixel areas PXA2, and each of one first sub pixel area PXA1 and one third sub pixel area PXA3.

For example, only portions of each of the first sub pixel area PXA1 and the corresponding pixel circuit area SPA (for example, the first pixel circuit area) may overlap each other. Only portions of each of the second sub pixel area PXA2 and the corresponding pixel circuit area SPA (for example, the second pixel circuit area) may overlap each other. Only portions of each of the third sub pixel area PXA3 and the corresponding pixel circuit area SPA (for example, the third pixel circuit area) may overlap each other.

According to the embodiment, the first to third sub pixel areas PXA1, PXA2, and PXA3 in which the individual sub pixels PXL1, PXL2, and PXL3 are defined are disposed so as to deviate from the corresponding pixel circuit area SPA. Therefore, an area in which light may not be emitted may be minimized, and thus a high-resolution display device DD may be provided.

The second contact portion CNT2 may be formed for each of the individual sub pixels PXL1, PXL2, and PXL3. Therefore, a cathode signal application through the second electrode ELT2 may be easily performed, and a cathode signal application path may be efficiently defined.

Hereinafter, a structure of the pixel PXL according to an embodiment is described with reference to FIGS. 6 and 7. Contents that may be repetitive to the above description are simplified or omitted.

FIG. 6 is a schematic cross-sectional view taken along I˜I′ of FIG. 5. FIG. 7 is a schematic cross-sectional view taken along II˜II′ of FIG. 5.

FIG. 6 shows the first sub pixel PXL1, the second sub pixel PXL2, and the third sub pixel PXL3. In FIG. 6, the description is given based on the first transistor T1 among the configurations included in the pixel circuit SPC described above with reference to FIG. 3. As an example, an embodiment in which the first transistor T1 may be provided in each of the first sub pixel PXL1, the second sub pixel PXL2, and the third sub pixel PXL3 is shown.

Referring to FIG. 6, the pixel PXL may include the substrate SUB, a pixel circuit part PCL, a display element part DPL, and a light control portion LCP.

The pixel circuit part PCL may be disposed on the substrate SUB. The pixel circuit part PCL may include a buffer layer BFL, the first transistor T1, a gate insulating layer GI, a first interlayer insulating layer ILD1, a second interlayer insulating layer ILD2, a bridge pattern BRP, a contact portion CNT, and a protective layer PSV.

According to an example, individual configurations of the pixel circuit part PCL may be defined in each of the first to third sub pixels PXL1, PXL2, and PXL3. Hereinafter, for convenience of description, the individual configurations defined in each of the first to third sub pixels PXL1, PXL2, and PXL3 are collectively described.

The buffer layer BFL may be disposed on the substrate SUB. The buffer layer BFL may prevent an impurity from being diffused from outside. The buffer layer BFL may include at least one of metal oxides such as silicon nitride (SiNx), silicon oxide (SiOx), silicon oxynitride (SiOxNy), and aluminum oxide (AlOx).

The first transistor T1 may be a thin film transistor. According to an embodiment, the first transistor T1 may be a driving transistor.

According to an embodiment, the first transistor T1 may be electrically connected to the light emitting element LD. For example, the first transistor T1 of the first sub pixel PXL1 may be electrically connected to the light emitting element LD disposed in the first sub pixel area PXA1. The first transistor T1 of the second sub pixel PXL2 may be electrically connected to the light emitting element LD disposed in the second sub pixel area PXA2. The first transistor T1 of the third sub pixel PXL3 may be electrically connected to the light emitting element LD disposed in the third sub pixel area PXA3.

According to an embodiment, the first transistor T1 may include an active layer ACT, a first transistor electrode TE1, a second transistor electrode TE2, and a gate electrode GE.

The active layer ACT may mean a semiconductor layer. The active layer ACT may be disposed on the buffer layer BFL. The active layer ACT may include at least one of polysilicon, amorphous silicon, and oxide semiconductor.

According to an embodiment, the active layer ACT may include a first contact region that may be in contact with the first transistor electrode TE1 and a second contact region that may be in contact with the second transistor electrode TE2. The first contact region and the second contact region may be a semiconductor pattern doped with an impurity. A region between the first contact region and the second contact region may be a channel region. The channel region may be an intrinsic semiconductor pattern that may not be doped with an impurity.

The gate electrode GE may be disposed on the gate insulating layer GI. A position of the gate electrode GE may correspond to a position of the channel region of the active layer ACT. For example, the gate electrode GE may be disposed on the channel region of the active layer ACT with the gate insulating layer GI interposed therebetween.

The gate insulating layer GI may be disposed on the active layer ACT. The gate insulating layer GI may include an inorganic material. According to an example, the gate insulating layer GI may include at least one of silicon nitride (SiNx), silicon oxide (SiOx), silicon oxynitride (SiOxNy), and aluminum oxide (AlOx).

The first interlayer insulating layer ILD1 may be positioned on the gate electrode GE. Similarly to the gate insulating layer GI, the first interlayer insulating layer ILD1 may include at least one of silicon nitride (SiNx), silicon oxide (SiOx), silicon oxynitride (SiOxNy), and aluminum oxide (AlOx).

The first transistor electrode TE1 and the second transistor electrode TE2 may be positioned on the first interlayer insulating layer ILD1. The first transistor electrode TE1 may pass through the gate insulating layer GI and the first interlayer insulating layer ILD1 and may be in contact with the first contact region of the active layer ACT, and the second transistor electrode TE2 may pass through the gate insulating layer GI and the first interlayer insulating layer ILD1 and may be in contact with the second contact region of the active layer ACT. According to an example, the first transistor electrode TE1 may be a drain electrode, and the second transistor electrode TE2 may be a source electrode, but the disclosure is not limited thereto.

The second interlayer insulating layer ILD2 may be positioned on the first transistor electrode TE1 and the second transistor electrode TE2. Similarly to the first interlayer insulating layer ILD1 and the gate insulating layer GI, the second interlayer insulating layer ILD2 may include an inorganic material. The inorganic material may include at least one of the materials provided as an example of the configuration material of the first interlayer insulating layer ILD1 and the gate insulating layer GI, for example, silicon nitride (SiNx), silicon oxide (SiOx), silicon oxynitride (SiOxNy), and aluminum oxide (AlOx).

The bridge pattern BRP may be disposed on the second interlayer insulating layer ILD2. The bridge pattern BRP may be connected to the first transistor electrode TE1 through a contact hole passing through the second interlayer insulating layer ILD2.

The protective layer PSV may be positioned on the second interlayer insulating layer ILD2. The protective layer PSV may cover the bridge pattern BRP. The protective layer PSV may be provided in a form including an organic insulating layer, an inorganic insulating layer, or the organic insulating layer disposed on the inorganic insulating layer, but is not limited thereto.

According to an embodiment, the first contact portion CNT1 connected to one region of the bridge pattern BRP may be formed on the protective layer PSV. According to an example, the anode signal provided to the light emitting element LD may be moved through the first contact portion CNT1.

The display element part DPL may be disposed on the pixel circuit part PCL. The display element part DPL may include the first electrode ELT 1, a first insulating layer INS1, a first connection electrode COL1, a second connection electrode COL2, a second insulating layer INS2, the light emitting element LD, a partition wall structure 300, and the second electrode ELT2.

According to an example, individual configurations of the display element part DPL may be defined in each of the first to third sub pixels PXL1, PXL2, and PXL3.

The first electrode ELT1 may be disposed on the protective layer PSV. The first electrode ELT1 may be disposed under the light emitting element LD. The first electrode ELT1 may be connected to the bridge pattern BRP through the first contact portion CNT1.

According to an embodiment, the first electrode ELT1 may be electrically connected to the light emitting element LD. According to an example, the first electrode ELT1 may provide an electrical signal provided from the first transistor T1 to the light emitting element LD. The first electrode ELT1 may apply the anode signal to the light emitting element LD.

According to an embodiment, the first electrode ELT1 may include a conductive material. For example, the first electrode ELT1 may include a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof. However, the first electrode ELT1 is not limited to the above-described example.

The first insulating layer INS1 may be disposed on the protective layer PSV and cover at least a portion of the first electrode ELT1. The first insulating layer INS1 may stabilize an electrical connection of the first electrode ELT1.

According to an example, the first insulating layer INS1 may include at least one of silicon nitride (SiNx), silicon oxide (SiOx), silicon oxynitride (SiOxNy), and aluminum oxide (AlOx), but is not limited thereto.

The first connection electrode COL1 may be disposed on the first electrode ELT1. A surface of the first connection electrode COL1 may be connected to the light emitting element LD, and another surface of the first connection electrode COL may be connected to the first electrode ELT1.

According to an embodiment, the first connection electrode COL1 may include a conductive material to electrically connect the first electrode ELT1 and the light emitting element LD. For example, the first connection electrode COL1 may be electrically connected to a second semiconductor layer 13 of the light emitting element LD. According to an embodiment, the first connection electrode COL1 may include a conductive material having a reflective property to reflect light emitted from the light emitting element LD, thereby improving light emission efficiency of the pixel PXL.

The second connection electrode COL2 may be disposed on the first insulating layer INS1. The second connection electrode COL2 may include a conductive material to electrically connect another line (for example, the common power line 320 of FIG. 7) and the partition wall structure 300. Contents regarding an electrical connection structure of the second connection electrode COL2 are described later with reference to FIG. 7.

According to an embodiment, the first connection electrode COL1 and the second connection electrode COL2 may be bonding metals bonding-combined to another configuration. The first connection electrode COL1 may be bonding-combined to the light emitting element LD, and the second connection electrode COL2 may be bonding-combined to the partition wall structure 300.

The light emitting element LD may be included in each of the first to third sub pixels PXL1, PXL2, and PXL3. The light emitting element LD may be configured to emit light by including a first semiconductor layer 11, the second semiconductor layer 13, and an active layer 12 interposed between the first and second semiconductor layers 11 and 13. According to an embodiment, the light emitting element LD may further include a first electrode layer EEL1.

According to an embodiment, light emitting elements LD may be provided and may be disposed in each of the first to third sub pixel areas PXA1, PXA2, and PXA3.

According to an embodiment, the light emitting element LD may be provided in a column shape extending along a direction. The light emitting element LD may have a first end portion EP1 and a second end portion EP2. One of the first and second semiconductor layers 11 and 13 may be adjacent to the first end portion EP1 of the light emitting element LD. The other one of the first and second semiconductor layers 11 and 13 may be adjacent to the second end portion EP2 of the light emitting element LD.

According to an embodiment, the light emitting element LD may be a light emitting element manufactured in a column shape through an etching method or the like. In the specification, the term “column shape” encompasses a rod-like shape or a bar-like shape that may be long in a longitudinal direction (for example, an aspect ratio may be greater than 1), such as a circular column or a polygonal column, and a shape of a cross section is not particularly limited. For example, a length of the light emitting element LD may be greater than a diameter (or a width of the cross section) thereof.

According to an embodiment, the light emitting element LD may have a size as small as nano scale to micro scale (nanometer scale to micrometer scale). For example, each of the light emitting elements LD may have a diameter (or width) and/or a length of a nano scale to micro scale range. However, the size of the light emitting element LD is not limited thereto.

The first semiconductor layer 11 may be a first conductivity type semiconductor layer. For example, the first semiconductor layer 11 may include an N-type semiconductor layer. For example, the first semiconductor layer 11 may include at least one semiconductor material among InAlGaN, GaN, AlGaN, InGaN, AlN, and InN, and may include an N-type semiconductor layer doped with a first conductivity type dopant such as Si, Ge, and Sn. However, the material configuring the first semiconductor layer 11 is not limited thereto.

The active layer 12 may be disposed on the first semiconductor layer 11 and may be formed in a single-quantum well or multi-quantum well structure. For example, in case that the active layer 12 is formed in the multi-quantum well structure, in the active layer 12, a barrier layer (not shown), a strain reinforcing layer, and a well layer may be repeatedly stacked periodically as one unit. The strain reinforcing layer may have a lattice constant smaller than that of the barrier layer, and thus may further reinforce a strain, for example, a compression strain, applied to the well layer. However, a structure of the active layer 12 is not limited to the above-described embodiment.

According to an embodiment, the active layer 12 may emit light having a wavelength of about 400 nm to about 900 nm. According to an example, the active layer 12 may include a material such as AlGaN and InAlGaN, but is not limited to the above-described example.

The second semiconductor layer 13 may be disposed on the active layer 12 and may include a semiconductor layer of a type different from that of the first semiconductor layer 11. For example, the second semiconductor layer 13 may include a P-type semiconductor layer. For example, the second semiconductor layer 13 may include at least one semiconductor material among InAlGaN, GaN, AlGaN, InGaN, AlN, and InN, and may include a P-type semiconductor layer doped with a second conductivity type dopant such as Mg. However, the material configuring the second semiconductor layer 13 is not limited thereto, and various other materials may configure the second semiconductor layer 13.

In case that a voltage greater than or equal to a threshold voltage is applied to both ends of the light emitting element LD, electron-hole pairs are combined in the active layer 12, and thus the light emitting element LD emits light. By controlling the light emission of the light emitting element LD using this principle, the light emitting element LD may be used as a light source of various light emitting devices including a pixel of a display device.

The first electrode layer EEL1 may be positioned adjacent to the second end portion EP2 of the light emitting element LD, and may be disposed on the first connection electrode COLI. The first electrode layer EEL1 may be positioned between the first connection electrode COL1 and the second semiconductor layer 13.

According to an embodiment, the first electrode layer EEL1 may include a conductive material. For example, the first electrode layer EEL1 may include at least one of Cr, Ti, Al, Au, Ni, and an oxide or an alloy thereof, but is not limited to the above-described example.

According to an embodiment, the first electrode layer EEL1 may be electrically connected to the first electrode ELT1. The first electrode layer EEL1 may be a contact electrode layer to which a signal provided through the first electrode ELT1 may be applied.

According to an embodiment, the light emitting element LD may further include a first insulating film INF1 provided on a surface. The first insulating film INF1 may be formed of a single film or a double film, but is not limited thereto, and may be formed of multiple films. According to an example, the first insulating film INF1 may include an inorganic material.

For example, the first insulating film INF1 may include at least one insulating material among silicon oxide (SiOx), silicon nitride (SiNx), silicon oxynitride (SiOxNy), aluminum oxide (AlOx), and titanium oxide (TiOx), and may be configured as a single layer or multiple layers.

The partition wall structure 300 may be disposed on the protective layer PSV. The partition wall structure 300 may be disposed on the second connection electrode COL2. The partition wall structure 300 may be disposed between the adjacently disposed first to third sub pixels PXL1, PXL2, and PXL3.

For example, the partition wall structure 300 may be disposed between the first sub pixel PXL1 and the second sub pixel PXL2 or between the second sub pixel PXL2 and the third sub pixel PXL3. In other embodiments, although not shown in the drawing, the partition wall structure 300 may be disposed between the first sub pixel PXL1 and the third sub pixel PXL3.

According to an embodiment, the partition wall structure 300 may have a shape surrounding each of the first to third sub pixel areas PXA1, PXA2, and PXA3 in a plan view.

According to an embodiment, the partition wall structure 300 may have a shape protruding in a display direction (for example, a third direction DR3) in which the display device DD emits light. In a plan view, the partition wall structure 300 may not overlap the light emitting element LD.

According to an embodiment, the partition structure 300 may include a first partition wall semiconductor layer 11′, a partition wall active layer 12′, a second partition wall semiconductor layer 13′, a second electrode layer EEL2, and a second insulating film INF2.

According to an embodiment, the first partition wall semiconductor layer 11′ may be formed in the same process and may include the same material as the first semiconductor layer 11. The partition active layer 12′ may be formed in the same process and may include the same material as the active layer 12. The second partition wall semiconductor layer 13′ may be formed in the same process and may include the same material as the second semiconductor layer 13. The second electrode layer EEL2 may be formed in the same process and may include the same material as the first electrode layer EEL1. The second insulating film INF2 may be formed in the same process and may include the same material as the first insulating film INF1.

According to an embodiment, each of the first partition wall semiconductor layer 11′, the partition wall active layer 12′, the second partition wall semiconductor layer 13′, the second electrode layer EELT2 included in the partition wall structure 300 may have conductivity.

The second insulating layer INS2 may be disposed on the first insulating layer INS1. The second insulating layer INS2 may cover at least a portion of the first connection electrode COL1 and the second connection electrode COL2.

According to an example, the second insulating layer INS2 may be provided between the light emitting elements LD bonding-combined to the first connection electrode COL1 and between the partition wall structures 300 bonding-combined to the second connection electrode COL2. The second insulating layer INS2 may be disposed between the light emitting elements LD to cover an outer surface of the light emitting element LD.

According to an embodiment, the second insulating layer INS2 may include at least one of the materials provided as an example with reference to the first insulating film INF1, but is not limited thereto.

The second electrode ELT2 may be disposed on the light emitting element LD.

The second electrode ELT2 may be disposed adjacent to the first semiconductor layer 11.

According to an embodiment, the second electrode ELT2 may be electrically connected to the light emitting element LD. The second electrode ELT2 may be electrically connected to the first semiconductor layer 11. According to an example, the second electrode ELT2 may apply the cathode signal to the light emitting element LD. The second electrode ELT2 may provide an electrical signal supplied from the common power line 320 and the second power line VSS to the light emitting element LD.

According to an embodiment, the second electrode ELT2 may include a conductive material. For example, the second electrode ELT2 may include a transparent conductive material. The second electrode ELT2 may include at least one of a conductive oxide such as indium tin oxide (ITO), indium zinc oxide (IZO), zinc oxide (ZnO), indium gallium zinc oxide (IGZO), and indium tin zinc oxide (ITZO), and a conductive polymer such as PEDOT (poly(3,4-ethylenedioxythiophene)). However, the second electrode ELT2 is not limited to the above-described example.

The light control portion LCP may be disposed on the display element part DPL. The light control portion LCP may change a wavelength of light provided from the display element part DPL. The light control portion LCP may include a color conversion portion CCL and a color filter portion CFL.

According to an embodiment, the light emitting elements LD disposed in each of the first sub pixel PXL1, the second sub pixel PXL2, and the third sub pixel PXL3 may emit light of the same color.

For example, the first sub pixel PXL1, the second sub pixel PXL2, and the third sub pixel PXL3 may include light emitting elements LD emitting light of a third color, for example, blue light. The light control portion LCP may be disposed on the first sub pixel PXL1, the second sub pixel PXL2, and the third sub pixel PXL3 to display a full-color image. However, the disclosure is not limited thereto, and the first sub pixel PXL1, the second sub pixel PXL2, and the third sub pixel PXL3 may include light emitting elements LD emitting light of different colors.

The color conversion portion CCL may define the first to third sub pixel areas PXA1, PXA2, and PXA3. According to an embodiment, the color conversion portion CCL may include a first passivation layer PSS1, a first wavelength conversion pattern WCP1, a second wavelength conversion pattern WCP2, a light transmission pattern LTP, and a light blocking layer LBL.

The first passivation layer PSS1 may be disposed between the display element part DPL and the light blocking layer LBL or the wavelength conversion pattern WCP. The first passivation layer PSS1 may seal (or cover) the wavelength conversion pattern WCP. The first passivation layer PSS1 may include at least one of materials provided as an example with reference to the first insulating film INF1, but is not limited to a specific example.

According to an example, an adhesive layer (not shown) may be interposed between the first passivation layer PSS1 and the second electrode ELT2. (Refer to FIG. 7) The adhesive layer may combine the first passivation layer PSS1 and the second electrode ELT2. The adhesive layer may include an adhesive material, and is not limited to a specific example.

The first wavelength conversion pattern WCP1 may be disposed to overlap an emission area EMA (for example, the first sub pixel area PXA1) of the first sub pixel PXL1. For example, the first wavelength conversion pattern WCP1 may be disposed in a space defined by the light blocking layer LBL and may overlap the first sub pixel area PXA1 in a plan view. Specifically, the light blocking layer LBL may include walls, and the first wavelength conversion pattern WCP1 may be provided in a space between the walls disposed in an area corresponding to the first sub pixel PXL1.

The second wavelength conversion pattern WCP2 may be disposed to overlap the emission area EMA (for example, the second sub pixel area PXA2) of the second sub pixel PXL2. For example, the second wavelength conversion pattern WCP2 may be disposed in a space defined by the light blocking layer LBL and may overlap the second sub pixel area PXA2 in a plan view. Specifically, the light blocking layer LBL may include walls, and the second wavelength conversion pattern WCP2 may be provided in a space between the walls disposed in an area corresponding to the second sub pixel PXL2.

The light transmission pattern LTP may be disposed to overlap the emission area EMA (for example, the third sub pixel area PXA3) of the third sub pixel PXL3. For example, the light transmission pattern LTP may be disposed in a space defined by the light blocking layer LBL and may overlap the third sub pixel area PXA3 in a plan view. Specifically, the light blocking layer LBL may include walls, and the light transmission pattern LTP may be provided in a space between the walls disposed in an area corresponding to the third sub pixel PXL3.

According to an embodiment, the first wavelength conversion pattern WCP1 may include first color conversion particles that convert light of a third color emitted from the light emitting element LD into light of a first color. For example, in case that the light emitting element LD is a blue light emitting element emitting blue light and the first sub pixel PXL1 is a red pixel, the first wavelength conversion pattern WCP1 may include a first quantum dot that converts the blue light emitted from the blue light emitting element into red light.

For example, the first wavelength conversion pattern WCP1 may include first quantum dots dispersed in a predetermined matrix material such as a base resin. The first quantum dot may absorb the blue light and shift a wavelength according to an energy transition to emit the red light. In case that the first sub pixel PXL1 is a pixel of a different color, the first wavelength conversion pattern WCP1 may include a first quantum dot corresponding to the color of the first sub pixel PXL1.

According to an embodiment, the second wavelength conversion pattern WCP2 may include second color conversion particles that convert light of a third color emitted from the light emitting element LD into light of a second color. For example, in case that the light emitting element LD is a blue light emitting element emitting blue light and the second sub pixel PXL2 is a green pixel, the second wavelength conversion pattern WCP2 may include a second quantum dot that converts the blue light emitted from the blue light emitting element light into green light.

For example, the second wavelength conversion pattern WCP2 may include second quantum dots dispersed in a predetermined matrix material such as a base resin. The second quantum dot may absorb the blue light and shift a wavelength according to an energy transition to emit the green light. In case that the second sub pixel PXL2 is a pixel of a different color, the second wavelength conversion pattern WCP2 may include a second quantum dot corresponding to the color of the second sub pixel PXL2.

The first quantum dot and the second quantum dot may have a shape of a globular shape, a pyramid shape, a multi-arm, or a cubic nanoparticle, a nanotube, a nanowire, a nanofiber, a nanoplate particle, or the like, but is not limited thereto, and the shape of the first quantum dot and the second quantum dot may be variously changed.

In an embodiment, an absorption coefficient of the first quantum dot and the second quantum dot may be increased by injecting the blue light having a relatively short wavelength in a visible light area to each of the first quantum dot and the second quantum dot. Accordingly, finally, efficiency of light emitted from the first sub pixel PXL1 and the second sub pixel PXL2 may be increased, and excellent color reproducibility may be secured. Manufacturing efficiency of the display device may be increased by configuring the pixel unit of the first to third sub pixels PXL1, PXL2, and PXL3 using the light emitting elements LD (for example, blue light emitting elements) of the same color.

According to an embodiment, the light transmission pattern LTP may be provided to efficiently use the light of the third color emitted from the light emitting element LD. For example, in case that the light emitting element LD is a blue light emitting element emitting blue light and the third sub pixel PXL3 is a blue pixel, the light transmission pattern LTP may include at least one type of light scattering particles in order to efficiently use the light emitted from the light emitting element LD.

For example, the light transmission pattern LTP may include light scattering particles dispersed in a predetermined matrix material such as a base resin. For example, the light transmission pattern LTP may include light scattering particles such as silica, but a configuration material of the light scattering particles is not limited thereto. The light scattering particles may not be disposed in the third sub pixel area PXA3 in which the third sub pixel PXL3 may be formed. For example, the light scattering particles may be selectively included in the first wavelength conversion pattern WCP1 and/or the second wavelength conversion pattern WCP2.

According to an embodiment, the light blocking layer LBL may be disposed on the display element part DPL. The light blocking layer LBL may be disposed on the substrate SUB. The light blocking layer LBL may be disposed between the first passivation layer PSS1 and the second passivation layer PSS2. The light blocking layer LBL may be disposed to surround the first wavelength conversion pattern WCP1, the second wavelength conversion pattern WCP2, and the light transmission pattern LTP at a boundary between the first to third sub pixels PXL1, PXL2, and PXL3.

According to an embodiment, the light blocking layer LBL may define an emission area EMA and a non-emission area NEA of the first to third sub pixels PXL1, PXL2, and PXL3. The light blocking layer LBL included in the color conversion portion CCL may define the first to third sub pixel areas PXA1, PXA2, and PXA3.

For example, the light blocking layer LBL may not overlap the emission area EMA in a plan view. The light blocking layer LBL may overlap the non-emission area NEA in a plan view.

According to an embodiment, an area in which the light blocking layer LBL may not be disposed may be defined as the emission area EMA of the first to third sub pixels PXL1, PXL2, and PXL3. The emission area EMA of the first sub pixel PXL1 may be the first sub pixel area PXA1, the emission area EMA of the second sub pixel PXL2 may be the second sub pixel area PXA2, and the emission area EMA of the third sub pixel PXL3 may be the third sub pixel area PXA3.

According to an embodiment, the light blocking layer LBL may be formed of an organic material including at least one of graphite, carbon black, black pigment, or black dye, or may be formed of a metal material including chromium (Cr), but is not limited as long as the material of the light blocking layer LBL may be a material capable of blocking light transmission and absorbing light.

The second passivation layer PSS2 may be disposed between the color filter portion CFL and the light blocking layer LBL. The second passivation layer PSS2 may seal (or cover) the first wavelength conversion pattern WCP1, the second wavelength conversion pattern WCP2, and the light transmission pattern LTP. The second passivation layer PSS2 may include at least one of materials provided as an example with reference to the first insulating film INF1, but is not limited to a specific example.

The color filter portion CFL may be disposed on the color conversion portion CCL. The color filter portion CFL may include a color filter CF and a planarization layer PLA. Here, the color filter CF may include a first color filter CF1, a second color filter CF2, and a third color filter CF3.

The color filter CF may be disposed on the second passivation layer PSS2. In a plan view, the color filter CF may overlap the emission area EMA of the first to third sub pixels PXL1, PXL2, and PXL3.

For example, the first color filter CF1 may be disposed in the first sub pixel area PXA1, the second color filter CF2 may be disposed in the second sub pixel area PXA2, and the third color filter CF3 may be disposed in the third sub pixel area PXA3.

The first color filter CF1 may transmit light of a first color, any may not transmit light of a second color and light of a third color. For example, the first color filter CF1 may include a colorant corresponding to the first color.

The second color filter CF2 may transmit the light of the second color, and may not transmit the light of the first color and the light of the third color. For example, the second color filter CF2 may include a colorant corresponding to the second color.

The third color filter CF3 may transmit the light of the third color, and may not transmit the light of the first color and the light of the second color. For example, the third color filter CF3 may include a colorant corresponding to the third color.

The planarization layer PLA may be disposed on the color filter CF. The planarization layer PLA may cover the color filter CF. The planarization layer PLA may cancel a step difference generated by the color filter CF.

According to an example, the planarization layer PLA may include an organic insulating material. However, the disclosure is not limited thereto, and the planarization layer PLA may include an inorganic material provided as an example with reference to the first insulating film INF1.

A structure of the first to third sub pixels PXL1, PXL2, and PXL3 is not limited to the contents described above with reference to FIG. 6, and various structures may be appropriately selected to provide the display device DD according to an embodiment. For example, according to an embodiment, the display device DD may further include a low refractive index layer to improve light efficiency.

Referring to FIG. 7, an electric signal application path (for example, the cathode signal) to the light emitting element LD is described.

Referring to FIG. 7, the cathode signal may be provided to the light emitting element LD through the partition wall structure 300 and the second electrode ELT2.

According to an embodiment, the pixel PXL may further include the common power line 320, the second contact portion CNT2, and a partition electrode 340.

The common power line 320 may be disposed on the second interlayer insulating layer ILD2. The common power line 320 may be covered by the protective layer PSV. The common power line 320 may be formed in the same process and may include the same material as the bridge pattern BRP.

According to an embodiment, the common power line 320 may receive an electrical signal (for example, the cathode signal, a ground signal, or the like) from the second power line VSS. The common power line 320 may be electrically connected to the second electrode ELT2 through the second contact portion CNT2, the partition electrode 340, the second connection electrode COL2, and the partition wall structure 300.

The partition wall electrode 340 may be disposed on the protective layer PSV. The partition wall electrode 340 may be disposed between the partition wall structure 300 and the protective layer PSV. According to an example, in a plan view, the partition wall electrode 340 may overlap the second connection electrode COL2, the partition wall structure 300, and the second contact portion CNT2.

According to an embodiment, the partition wall electrode 340 may be formed in the same process and may include the same material as the first electrode ELT1.

According to an embodiment, the partition wall electrode 340 may receive the electrical signal from the common power line 320. The partition wall electrode 340 may be electrically connected to the second electrode ELT2 through the second connection electrode COL2 and the partition wall structure 300.

Accordingly, the electrical signal provided from the second power line VSS and the common power line 320 may be provided to the light emitting element LD through the partition wall structure 300 and the second electrode ELT2.

The light emitting element LD may receive the cathode signal through the second electrode ELT2 connected to the adjacent partition wall structure 300.

For example, referring to FIG. 7, the light emitting element LD disposed in the first sub pixel area PXA1 may be electrically connected to the second electrode ELT2 through the adjacent partition wall structure 300, and the light emitting element LD disposed in the third sub pixel area PXA3 may be electrically connected to the second electrode ELT2 through another partition wall structure 300.

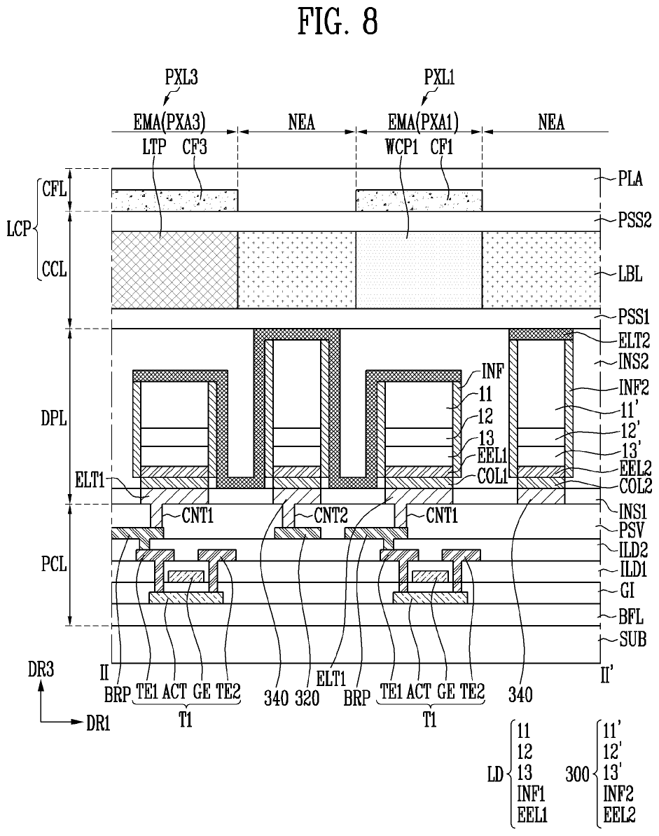

In other embodiments, according to an embodiment, a single partition wall structure 300 may be electrically connected to the light emitting elements LD through the second electrode ELT2. An embodiment is shown in FIG. 8. FIG. 8 is a cross-sectional view taken along II˜II′ of FIG. 5, and is a view in which some modified embodiments are reflected.

Referring to FIG. 8, the partition wall structure 300 may be electrically connected to adjacent light emitting elements LD through the second electrode ELT2.

Referring to FIG. 8, the second electrode ELT2 may be disposed between the partition wall structure 300 and adjacent light emitting elements LD, and may function as a path through which an electrical signal moves.

According to an embodiment, the partition wall structure 300 may be electrically connected to the adjacent light emitting elements LD. For example, the partition wall structure 300 may be electrically connected through the common power line 320 and the second contact portion CNT2, and may be electrically connected to the light emitting element LD in the adjacent first sub pixel area PXA1 and the light emitting element LD in the adjacent third sub pixel area PXA3. Here, the second electrode ELT2 may be electrically connected to the light emitting elements LD disposed adjacent to the partition wall structure 300 to provide the cathode signal.

According to an embodiment, the partition wall structure 300 may be provided that mediates an electrical connection structure between the common power line 320 and the second electrode ELT2, and the partition wall structure 300 may be electrically connected to the light emitting elements LD, which may be respectively disposed in adjacent pixel areas, through the same second electrode ELT2, selectively. Accordingly, a degree of freedom of an electrode connection structure to the common power line 320 may be increased.

However, an electrical connection structure between the light emitting element LD and the second electrode ELT2 is not limited to the above-described example.

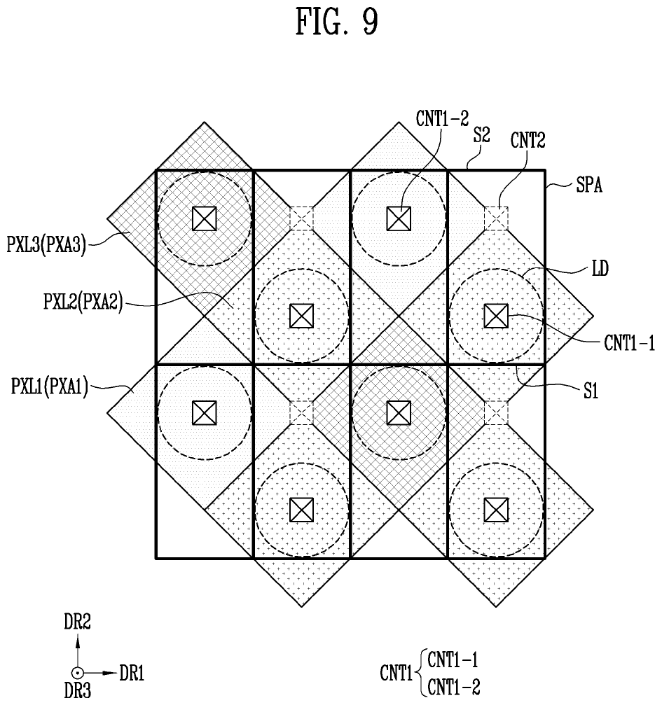

Another electrical connection structure between the light emitting element LD and the second electrode ELT2 is described with reference to FIG. 9. FIG. 9 is a plan view schematically illustrating a pixel according to another embodiment.

Referring to FIG. 9, the second contact portion CNT2 may be formed at a regular distance, and thus that the second contact portion CNT2 may not be formed in at least a portion of the pixel circuit area SPA. For example, the second contact portion CNT2 may be disposed in one pixel circuit area SPA, the second contact portion CNT2 may not be disposed in another pixel circuit area SPA adjacent in the first direction DR1.

According to an embodiment, the second contact portion CNT2 shown in FIG. 9 may be disposed adjacent to the second side S2 of the pixel circuit area SPA.

According to an embodiment, the cathode signal provided through any one of the second contact portions CNT2 may be provided to the light emitting elements LD respectively disposed in at least two or more of the adjacent first to third sub pixel areas PXA1, PXA2, and PXA3.

For example, referring to FIG. 9, the pixel circuit area SPA in which the second contact portion CNT2 may be disposed and the pixel circuit area SPA in which the second contact portion CNT2 may not be disposed may be alternately disposed in the first direction DR1. In this case, the cathode signal provided through one second contact portion CNT2 may be provided to both of the light emitting element LD disposed in the corresponding pixel circuit area SPA and the light emitting element LD disposed in the pixel circuit area SPA adjacent to a side (for example, adjacent in the first direction DR1).

However, the disclosure is not limited to the above-described example, and the cathode signal provided through the one second contact portion CNT2 may be provided to the light emitting element LD disposed in each of four adjacent sub pixel areas, based on a position of the second contact portion CNT2.

According to an embodiment, the second contact portion CNT2 may not be formed in each of all of the pixel circuit areas SPA. Accordingly, the freedom degree of the electrode connection structure may be improved.

Hereinafter, an area in which the display area DA and the non-display area NDA of the display device DD according to an embodiment are adjacent to each other is described with reference to FIGS. 10 and 11.

FIG. 10 is an enlarged schematic view of EA2 of FIG. 2. FIG. 11 is a cross-sectional schematic view taken along of FIG. 10. FIG. 10 is a plan view illustrating the area in which the display area DA and the non-display area NDA are adjacent to each other of the display device DD according to an embodiment.

Referring to FIG. 10, at least a portion of the first to third sub pixel areas PXA1, PXA2, and PXA3 may be disposed in the non-display area NDA.

Hereinafter, for convenience of description, an embodiment in which a portion of the second sub pixel area PXA2 overlaps the non-display area NDA in a plan view is described.

According to an embodiment, at least a portion of the second sub pixel area PXA2 may be disposed in the non-display area NDA. The second sub pixel area PXA2 may have a shape protruding in a predetermined direction, and thus at least a portion of the second sub pixel area PXA2 may overlap the non-display area NDA in a plan view.

For example, the second sub pixel area PXA2 may have a rhombus shape, a center of the second sub pixel area PXA2 may be disposed in the display area DA, and a vertex of the second sub pixel area PXA2 protruding in the first direction DR1 may be disposed in the non-display area NDA. In other embodiments, although not shown in the drawing, the center of the second sub pixel area PXA2 may be disposed in the display area DA, and the vertex of the second sub pixel area PXA2 protruding in the second direction DR2 may be disposed in the non-display area NDA.

Referring to FIG. 11, the display device DD according to an embodiment may further include a cover layer 400.

The cover layer 400 may define a boundary line 420 positioned between the display area DA and the non-display area NDA. Here, the boundary line 420 may mean a line defined between the display area DA and the non-display area NDA. The cover layer 400 may be disposed in the non-emission area NEA in the non-display area DA.

For example, the cover layer 400 may be disposed in the outermost area (for example, an area surrounding the display area DA), may cover at least a portion of the emission area EMA in which the light blocking layer LBL may not be disposed, and may provide this to the non-display area NDA.

For example, the cover layer 400 may cover a portion of the second sub pixel area PXA2, and the emission area EMA of the second sub pixel PXL2 covered by the cover layer 400 may be provided to the non-display area NDA.

According to an embodiment, the cover layer 400 may be disposed on the display element part DPL. The cover layer 400 may be disposed between the light blocking layer LBL and the color filter portion CFL. For example, the cover layer 400 may be disposed on the same layer as the third insulating layer INS3 disposed between the second passivation layer PSS2 and the color filter portion CFL. Here, the third insulating layer INS3 may cancel a step difference generated by the cover layer 400 and may include at least one of materials provided as an example with reference to the first insulating film INF1. However, the disclosure is not limited to the above-described example, and the cover layer 400 may be disposed on the color filter portion CFL according to an embodiment.

According to an embodiment, the cover layer 400 may be formed of an organic material including at least one of graphite, carbon black, black pigment, or black dye, or may be formed of a metal material including chromium (Cr), but is not limited as long as the material of the cover layer 400 may be a material capable of blocking light transmission and absorbing light.

According to an embodiment, the cover layer 400 may cover an uneven line of the first to third sub pixel areas PXA1, PXA2, and PXA3 disposed adjacent to an outer periphery of the display area DA. Accordingly, a uniform outline of the display area DA may be formed without necessarily requiring a separate driving algorithm design.

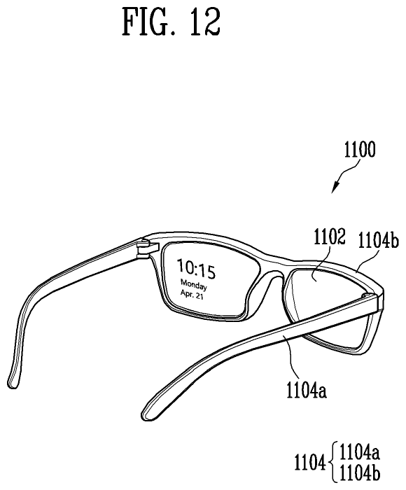

Hereinafter, an application field of the display device DD according to an embodiment is described with reference to FIGS. 12 to 15. FIGS. 12 to 15 are diagrams schematically illustrating an example to which a display device according to an embodiment may be applied. According to an example, the display device DD may be applied to a smart phone, a notebook computer, a tablet PC, a television, and the like, and may be applied to various other embodiments.

Referring to FIG. 12, a display device according to an embodiment may be applied to a smart glass 1100 including a frame 1104 and a lens portion 1102. The smart glass 1100 may be a wearable electronic device that may be worn on a face of a user, and may be a structure in which a portion of the frame 1104 may be folded or unfolded. For example, the smart glass 1100 may be a wearable device for augmented reality (AR).

The frame 1104 may include a housing 1104b supporting the lens portion 1102 and a leg portion 1104a for wearing of the user. The leg portion 1104a may be connected to the housing 1104b by a hinge and may be folded or unfolded.

The frame 1104 may include a battery, a touch pad, a microphone, a camera, and the like therein. The frame 1104 may include a projector that outputs light, a processor that controls a light signal or the like, and the like therein.

The lens portion 1102 may be an optical member that transmits light or reflects light. The lens portion 1102 may include glass, transparent synthetic resin, or the like.

The lens portion 1102 may reflect an image by a light signal transmitted from the projector of the frame 1104 by a rear surface (for example, a surface of a direction facing an eye of the user) of the lens portion 1102 to allow the eye of the user to recognize the image. For example, as shown in the drawing, the user may recognize information such as time and date displayed on the lens portion 1102. For example, the lens portion 1102 may be one type of a display device, and the display device according to the above-described embodiment may be applied to the lens portion 1102.

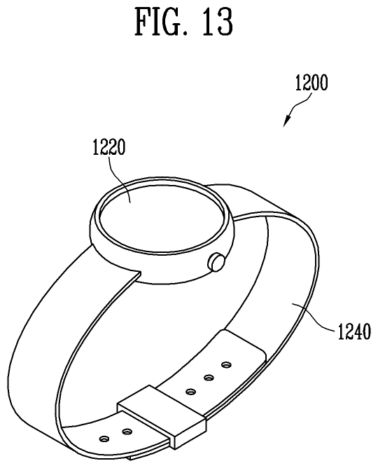

Referring to FIG. 13, a display device according to an embodiment may be applied to a smart watch 1200 including a display portion 1220 and a strap portion 1240.

The smart watch 1200 may be a wearable electronic device and may have a structure in which the strap portion 1240 may be mounted on a wrist of a user. Here, the display device according to the embodiment may be applied to the display portion 1220, and thus image data including time information may be provided to the user.

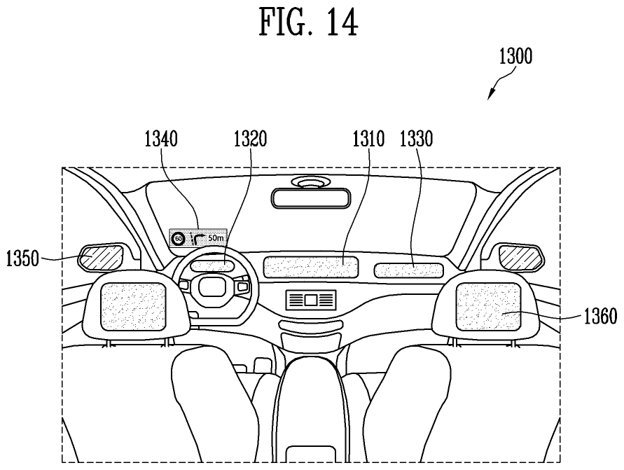

Referring to FIG. 14, a display device according to an embodiment may be applied to an automotive display. Here, the automotive display 1300 may mean an electronic device provided inside and outside a vehicle to provide image data.

According to an example, the display device may be applied to at least one of an infotainment panel 1310, a cluster 1320, a co-driver display 1330, a head-up display 1340, a side mirror display 1350, and a rear seat display 1360, which are provided in the vehicle.

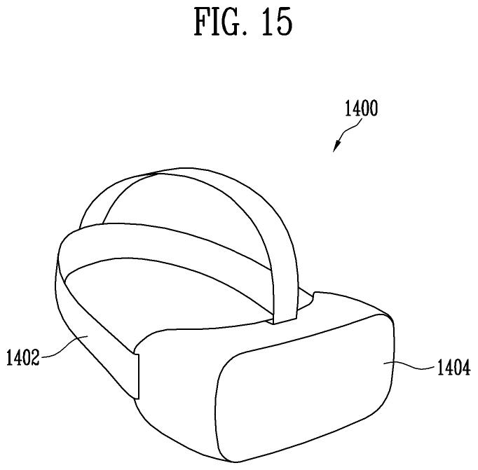

Referring to FIG. 15, a display device according to an embodiment may be applied to a head mounted display (HMD) 1400 including a head mounting band 1402 and a display storage case 1404. The HMD 1400 may be a wearable electronic device that may be worn on a head of a user.

The head mounting band 1402 may be a portion connected to the display storage case 1404 and fixing the display storage case 1404. In the drawing, the head mounting band 1402 is shown to be able to surround an upper surface and both side surfaces of the head of the user, but the disclosure is not limited thereto. The head mounting band 1402 may be for fixing the HMD 1400 to the head of the user, and may be formed in an eyeglass frame form or a helmet form.

The display storage case 1404 may accommodate the display device and may include at least one lens. The at least one lens may be a portion that provides an image to the user. For example, the display device according to an embodiment may be applied to a left-eye lens and a right-eye lens implemented in the display storage case 1404.

The application field of the display device DD according to an embodiment is not limited to the above-described examples, and may be applied to various fields according to an embodiment.

The above description is merely an example of the technical spirit of the disclosure, and those skilled in the art to which the disclosure pertains will be able to make various modifications and variations without departing from the essential characteristics of the disclosure. Therefore, the embodiments of the disclosure described above may be implemented separately or in combination with each other.

Therefore, the embodiments disclosed herein are not intended to limit the disclosure, but rather to illuminate the technical spirit of the disclosure. The scope of the disclosure should be interpreted by the following claims, including equivalents thereof.

What is claimed is:

1. A display device comprising:
light emitting elements disposed on a substrate;
a first electrode and a second electrode that are disposed on the substrate and electrically connected to each of the light emitting elements;
a pixel circuit electrically connected to at least one of the light emitting elements, wherein
the pixel circuit is disposed in each of a plurality of pixel circuit areas that are disposed in a matrix form defined by a first direction and a second direction intersecting the first direction,
a first contact portion and a second contact portion are disposed in each of the plurality of pixel circuit areas, wherein
the first contact portion electrically connects the pixel circuit and the first electrode, and
the second contact portion electrically connects a common power line and the second electrode, and
the first contact portion and the second contact portion are alternately disposed along the first direction in a plan view.

2. The display device according to claim 1, further comprising:
a first sub pixel area where light of a first color is emitted;
a second sub pixel area where light of a second color is emitted; and
a third sub pixel area where light of a third color is emitted,
wherein the light emitting elements include:
a first light emitting element overlapping the first sub pixel area;
a second light emitting element overlapping the second sub pixel area; and
a third light emitting element overlapping the third sub pixel area.

3. The display device according to claim 1, wherein
the pixel circuit includes a transistor and a storage capacitor,
the pixel circuit is electrically connected to any one of first signal lines extending in the first direction,
the pixel circuit is electrically connected to any one of second signal lines extending in the second direction, and
each of the plurality of pixel circuit areas is disposed in an overlap area between an first area and a second area, wherein the first area is between the first signal lines adjacent in the second direction, and the second area is between the second signal lines adjacent in the first direction.

4. The display device according to claim 2, wherein the plurality of pixel circuit areas comprises:
a first pixel circuit area in which a first pixel circuit electrically connected to the first light emitting element is disposed;
a second pixel circuit area in which a second pixel circuit electrically connected to the second light emitting element is disposed; and
a third pixel circuit area in which a third pixel circuit electrically connected to the third light emitting element is disposed.

5. The display device according to claim 4, further comprising:
a color conversion portion defining the first sub pixel area, the second sub pixel area, and the third sub pixel area, wherein
the color conversion portion includes:
a first wavelength conversion pattern overlapping the first sub pixel area;
a second wavelength conversion pattern overlapping the second sub pixel area; and
a light transmission pattern overlapping the third sub pixel area, and
the first light emitting element, the second light emitting element, and the third light emitting element emit light of the third color.

6. The display device according to claim 1, wherein
the first contact portion is disposed in one of the plurality of pixel circuit areas and the second contact portion is disposed in another of the plurality of pixel circuit areas,
another second contact portion is disposed in the one of the plurality of pixel circuit areas and another first contact portion is disposed in the another of the plurality of pixel circuit areas, and
the one of the plurality of pixel circuit areas and the another of the plurality of pixel circuit areas are adjacent to each other in the first direction.

7. The display device according to claim 2, wherein
the first sub pixel area, the second sub pixel area, and the third sub pixel area have a first shape, and
each of the plurality of pixel circuit areas has a second shape different from the first shape.

8. The display device according to claim 7, wherein
the first shape is a rhombus shape, and
the second shape is a rectangular shape.

9. The display device according to claim 2, wherein each of the plurality of pixel circuit areas overlaps at least a portion of each of the first sub pixel area, the second sub pixel area, and the third sub pixel area in a plan view.

10. The display device according to claim 4, wherein
the first pixel circuit area and the first sub pixel area partially overlap each other in a plan view,
the second pixel circuit area and the second sub pixel area partially overlap each other in a plan view, and
the third pixel circuit area and the third sub pixel area partially overlap each other in a plan view.

11. The display device according to claim 1, wherein the first contact portion and the second contact portion are disposed in each of the plurality of pixel circuit areas.

12. The display device according to claim 2, wherein
the first contact portion includes:
a (1-1)-th contact portion disposed adjacent to a first side of a first circuit area which is one of the plurality of pixel circuit areas; and
a (1-2)-th contact portion disposed adjacent to a second side of a second circuit area which is another of the plurality of pixel circuit areas, and
the second side is another side of the first side in the second direction.

13. The display device according to claim 12, wherein the second contact portion includes:
a (2-1)-th contact portion disposed adjacent to the first side in the second circuit area; and
a (2-2)-th contact portion disposed adjacent to the second side in the first circuit area.

14. The display device according to claim 1, wherein the first contact portion overlaps at least one of the light emitting elements in a plan view.

15. The display device according to claim 1, wherein the common power line provides a cathode signal to the light emitting elements.

16. The display device according to claim 2, further comprising:
a partition wall structure disposed between areas adjacent to each other among the first sub pixel area, the second sub pixel area, and the third sub pixel area, in a plan view,
wherein the light emitting elements are electrically connected to the common power line through the second electrode, the partition wall structure, and the second contact portion.

17. The display device according to claim 1, wherein the first contact portion and the second contact portion are alternately disposed along the second direction, in a plan view.

18. The display device according to claim 1, further comprising:
a display area;
a non-display area surrounding at least a portion of the display area;
a cover layer disposed in the non-display area adjacent to a boundary area between the display area and the non-display area; and
a sub pixel area overlapping at least a portion of the light emitting elements,
wherein at least a portion of the sub pixel area overlaps the cover layer in a plan view.

19. The display device according to claim 18, wherein the cover layer defines the boundary area between the display area and the non-display area.

20. A display device comprising:
light emitting elements disposed on a substrate and including:
a first light emitting element disposed in a first sub pixel area; and
a second light emitting element disposed in a second sub pixel area that is adjacent to the first sub pixel area;
a first electrode and a second electrode that are disposed on the substrate and electrically connected to each of the light emitting elements;
a pixel circuit electrically connected to at least one of the light emitting elements; and
a partition wall structure disposed between the first sub pixel area and the second sub pixel area, wherein
the pixel circuit and the first electrode are electrically connected through a first contact portion,
a common power line and the second electrode are electrically connected through a second contact portion,
the pixel circuit is disposed in each of a plurality of pixel circuit areas that are disposed in a matrix form defined by a row direction according and a column direction,
a shape of each of the first sub pixel area and the second sub pixel area and a shape of the pixel circuit area are different from each other, and
the common power line is electrically connected to the first light emitting element and the second light emitting element through the second contact portion and the partition wall structure.
